(19) United States
(12) Patent Application Publication
(10) Pub. No.: US 2025/0331377 A1
(43) Pub. Date: Oct. 23, 2025

(54) DISPLAY PANEL

(71) Applicant: Samsung Display Co., Ltd., Yongin-si (KR)

(72) Inventor: Junwon Choi, Yongin-si (KR)

(21) Appl. No.: 18/957,468

(22) Filed: Nov. 22, 2024

(30) Foreign Application Priority Data
Apr. 23, 2024 (KR) 10-2024-0054278

(51) Int. Cl. H10K 59/131

(52) U.S. Cl. CPC H10K 59/131

(57) ABSTRACT

Provided is a display panel including a substrate including a display area, an opening area within the display area, and an intermediate area between the opening area and the display area, a light-emitting diode in the display area, and including a sub-pixel electrode, an opposite electrode above the sub-pixel electrode, and an intermediate layer between the sub-pixel electrode and the opposite electrode, an organic pattern layer in the intermediate area above the substrate, and defining a first groove and a second groove, a conductive pattern layer in the second groove, and including a tip having an end protruding toward a center of the first groove in plan view, and a line electrically connected to the conductive pattern layer, and passing through the display area.

### CROSS-REFERENCE TO RELATED APPLICATION

The present application claims priority to, and the benefit of, Korean Patent Application No. 10-2024-0054278, filed on Apr. 23, 2024, in the Korean Intellectual Property Office, the entire disclosure of which is incorporated herein by reference.

### BACKGROUND

### 1. Field

One or more embodiments relate to a display panel including a light-emitting diode.

### 2. Description of the Related Art

In recent years, as uses of display panels have diversified and display panels have become thinner and lighter, their range of use has widened. As an area occupied by a display area within a display panel has increased, various functions combined with or linked to display panels have been added. To further increase this area and add more functions, research has been conducted to use a part of the display area for functions other than a function of expressing images.

### SUMMARY

One or more embodiments include a display panel including an opening area and an electronic device including the display panel.

Additional aspects will be set forth in part in the description which follows and, in part, will be apparent from the description, or may be learned by practice of the presented embodiments of the disclosure.

According to one or more embodiments, a display panel includes a substrate including a display area, an opening area within the display area, and an intermediate 1 area between the opening area and the display area, a light-emitting diode in the display area, and including a sub-pixel electrode, an opposite electrode above the sub-pixel electrode, and an intermediate layer between the sub-pixel electrode and the opposite electrode, an organic pattern layer in the intermediate area above the substrate, and defining a first groove and a second groove, a conductive pattern layer in the second groove, and including a tip having an end protruding toward a center of the first groove in plan view, and a line electrically connected to the conductive pattern layer, and passing through the display area.

The display panel may further include a cover layer above the conductive pattern layer, and including a conductive material.

The cover layer may include a first portion above an upper surface of the conductive pattern layer, and a second portion in the first groove and separated from the first portion.

The first portion may at least partially cover the tip of the conductive pattern layer.

The cover layer may continuously extend along an upper surface of the conductive pattern layer, side and lower surfaces of the tip, and an upper surface of a portion of the organic pattern layer in the first groove.

The cover layer and the sub-pixel electrode may include a same material.

The line may be integral with the conductive pattern layer.

The line may be under the conductive pattern layer, and may contact the conductive pattern layer in an area in which the line overlaps the second groove.

An insulating layer may be between the conductive pattern layer and the line, wherein the line is electrically connected to the conductive pattern layer through a contact hole in the insulating layer.

The line may include a scan line, a data line, or a voltage line.

The conductive pattern layer may surround the opening area in plan view.

The opposite electrode of the light-emitting diode may extend toward the intermediate area, and may include a first portion and a second portion separated from each other with respect to the tip, the second portion being in the first groove and directly contacting the tip of the conductive pattern layer.

According to one or more embodiments, a display panel includes a substrate including a first area, a second area at least partially surrounding the first area, and a third area between the first area and the second area, a light-emitting diode in the second area, and including a sub-pixel electrode, an opposite electrode above the sub-pixel electrode, and an intermediate layer between the sub-pixel electrode and the opposite electrode, a separator in the third area, a cover layer above the separator, and including a conductive material, and a line passing through the second area, wherein the separator includes an organic pattern layer above the substrate, and defining a groove, and a conductive pattern layer electrically connected to the line, above an upper surface of the organic pattern layer, and including a tip extending toward a center of the groove in plan view and having at least a portion covered by the cover layer.

The cover layer may include a first portion above the conductive pattern layer, and a second portion in the groove and separated from the first portion.

The cover layer may continuously extend by entirely covering the conductive pattern layer and the organic pattern layer in the groove.

The cover layer and the sub-pixel electrode may include a same material.

The line may be integral with the conductive pattern layer.

The line may be between the substrate and the conductive pattern layer, and may contact the conductive pattern layer.

An insulating layer may be between the conductive pattern layer and the line, wherein the line is electrically connected to the conductive pattern layer through a contact hole in the insulating layer.

The line may include a scan line, a data line, or a voltage line.

The separator may surround the first area in plan view.

The display panel may further include an electrode layer including a first portion above an upper surface of the conductive pattern layer, and a second portion in the groove and separated from the first portion.

The electrode layer may be above the cover layer.

The second portion of the electrode layer may directly contact the tip of the conductive pattern layer.

The electrode layer and the opposite electrode may include a same material.

### BRIEF DESCRIPTION OF THE DRAWINGS

The above and other aspects of certain embodiments of the disclosure will be more apparent from the following description taken in conjunction with the accompanying drawings, in which:

FIG. 1 is a perspective view schematically illustrating an electronic device according to one or more embodiments;

FIG. 2 is a cross-sectional view, taken along the line II-Il′, briefly illustrating the electronic device of FIG. 1 according to one or more embodiments;

FIG. 3 is a plan view schematically illustrating a display panel according to one or more embodiments;

FIG. 4 is an equivalent circuit diagram schematically illustrating a light-emitting diode of a sub-pixel arranged in a display area and a driving circuit electrically connected to the light-emitting diode, according to one or more embodiments;

FIG. 5 is a cross-sectional view illustrating a part of a display area of a display panel according to one or more embodiments;

FIG. 6 is a plan view illustrating a part of a display panel according to one or more embodiments;

FIG. 7 is a cross-sectional view, taken along the line VII-VII′, of a part of the display panel of FIG. 6 according to one or more embodiments;

FIG. 8 is a cross-sectional view, taken along the line VIII-VIII′, of a part of the display panel of FIG. 6 according to one or more embodiments;

FIG. 9 is a cross-sectional view, taken along the line IX-IX′, of a part of the display panel of FIG. 6 according to one or more embodiments;

FIG. 10 is a plan view illustrating a part of a display panel according to one or more other embodiments;

FIG. 11 is an example of a cross-sectional view, taken along the line X-X′, of a part of the display panel of FIG. 10 according to one or more embodiments;

FIG. 12 is an example of a cross-sectional view, taken along the line X-X′, of a part of the display panel of FIG. 10 according to one or more embodiments;

FIG. 13 is an example of a cross-sectional view, taken along the line X-X′, of a part of the display panel of FIG. 10, according to one or more embodiments;

FIG. 14 is an example of a cross-sectional view, taken along the line X-X′, of a part of the display panel of FIG. 10 according to one or more embodiments;

FIG. 15 is an enlarged cross-sectional view illustrating region XIV of FIG. 14;

FIG. 16 is an example of a cross-sectional view, taken along the line X-X′, of a part of the display panel of FIG. 10 according to one or more embodiments;

FIG. 17 is an enlarged cross-sectional view illustrating region XVI of FIG. 16;

FIG. 18 is an example of a cross-sectional view, taken along the line X-X′, of a part of the display panel of FIG. 10 according to one or more embodiments; and

FIG. 19 is a cross-sectional view illustrating a part of a display panel according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, 1 regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

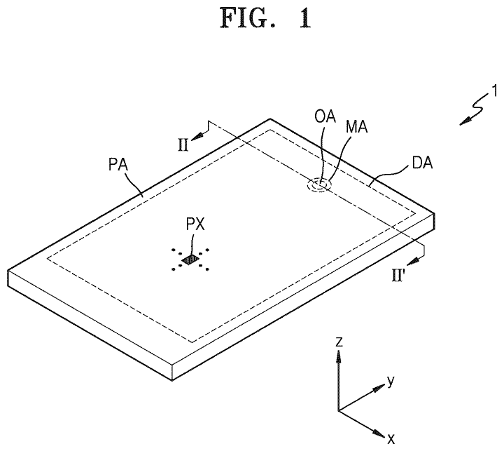

FIG. 1 is a perspective view schematically illustrating an electronic device 1 according to one or more embodiments.

Referring to FIG. 1, the electronic device 1 is configured to display moving images or still images, and may be used as a display screen of various products such as televisions, laptops, monitors, billboards, or Internet of Things (IoT) devices as well as portable electronic devices, such as a mobile phone, a smartphone, a tablet personal computer (PC), a mobile communication terminal, an electronic notebook, an electronic book, a portable multimedia player (PMP), a navigation, a ultra mobile PC (UMPC). In addition, the electronic device 1 according to one or more embodiments may be used for wearable devices, such as a smart watch, a watch phone, a glasses-type display, and a head-mounted display (HMD). In addition, the electronic device 1 according to one or more embodiments may be used as a display for an instrument panel of a vehicle, a center information display (CID) arranged on a center fascia or dashboard of a vehicle, a mirror display replacing side-view mirrors of a vehicle, or as displays arranged on the rear surfaces of the front seats as an entertainment for the backseat of a vehicle. For convenience of description, FIG. 1 shows a case where the electronic device 1 according to one or more embodiments is used as a smartphone.

1 In a plan view, the electronic device 1 may have a rectangular shape. For example, as shown in FIG. 1, the electronic device 1 may have a rectangular planar shape having a short side in an x-direction and a long side in a y-direction. A corner at which the short side in the x-direction meets the long side in the y-direction may be rounded to have a corresponding curvature or may be formed at a right angle. A planar shape of the electronic device 1 is not limited to a rectangle, but may be formed in other polygonal, elliptical, or irregular shapes.

The electronic device 1 may include an opening area OA, and a display area DA that surrounds at least the opening area OA (e.g., in plan view). The electronic device 1 may include an intermediate area MA positioned between the opening area OA and the display area DA, and a peripheral area PA arranged outside the display area DA to, for example, surround the display area DA. The intermediate area MA may have a closed loop shape that entirely surrounds the opening area OA in a plan view.

The opening area OA may be positioned inside the display area DA. In one or more embodiments, the opening area OA may be arranged in an upper center of the display area DA, as shown in FIG. 1. Alternatively, the opening area OA may be arranged in various ways, such as on an upper left side of the display area DA or on an upper right side of the display area DA. In FIG. 1, one opening area OA is shown.

However, in one or more other embodiments, a plurality of opening areas OA may be provided.

In one or more embodiments, the opening area OA may be a first area, the display area DA may be a second area, and the intermediate area MA may be a third area.

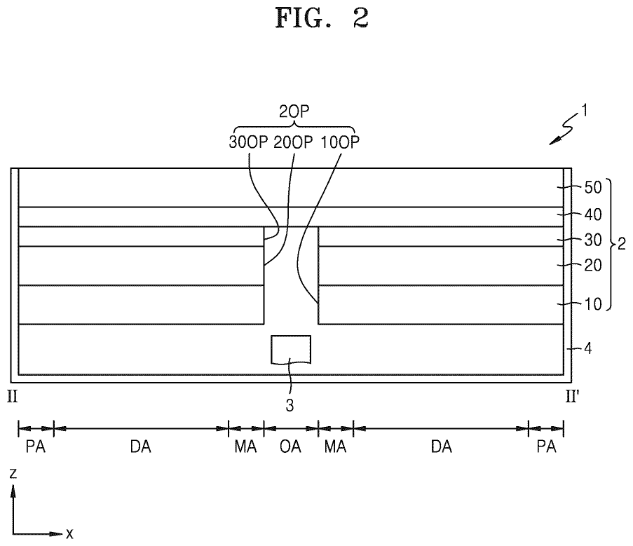

FIG. 2 is a cross-sectional view briefly illustrating the electronic device 1 of FIG. 1, taken along the line II-Il′, according to one or more embodiments.

Referring to FIG. 2, the electronic device 1 may include a display panel 2 and a component 3 arranged in the opening area OA of the display panel 2. The display panel 2 and the component 3 may be accommodated in a housing 4.

The display panel 2 may include an image generation layer 10, an input detection layer 20, an optical functional layer 30, an adhesive layer 40, and a cover window 50.

To display an image, the image generation layer 10 may include display elements that emit light. The display element may include a light-emitting diode, for example, an organic light-emitting diode including an organic emission layer. In one or more other embodiments, the light-emitting diode may be an inorganic light-emitting diode including an inorganic material. The inorganic light-emitting diode may include a PN junction diode including inorganic semiconductor-based materials. When a voltage is applied to the PN junction diode in a forward direction, holes and electrons are injected, and energy generated by recombination of the holes and electrons may be converted into light energy to emit light of a corresponding color. The inorganic light-emitting diode described above may have a width of several to hundreds of micrometers, or several to hundreds of nanometers. In some embodiments, the image generation layer 10 may include a quantum dot light-emitting diode. For example, the emission layer of the image generation layer 10 may include an organic material, an inorganic material, quantum dots, both an organic material and quantum dots, or both an inorganic material and quantum dots.

The input detection layer 20 may obtain coordinate information according to an external input, for example, a touch event. The input detection layer 20 may include a touch electrode (or sensing electrode), and trace lines connected to the touch electrode. The input detection layer 20 may be located on the image generation layer 10. The input detection layer 20 may detect an external input by using a mutual capacitance method or/and a self-capacitance method.

The input detection layer 20 may be formed directly on the image generation layer 10 or may be separately formed and then coupled onto the input detection layer 20 through an adhesive layer, such as an optically clear adhesive. For example, the input detection layer 20 may be continuously formed after a process of forming the image generation layer 10, in which case the adhesive layer may not be between the input detection layer 20 and the image generation layer 10. In FIG. 2, the input detection layer 20 is between the image generation layer 10 and the optical functional layer 30. However, in one or more other embodiments, the input detection layer 20 may be located on the optical functional layer 30.

The optical functional layer 30 may include an anti-reflection layer. The anti-reflection layer may reduce reflectivity of light (external light) incident toward the display panel 2 from the outside through the cover window 50. The anti-reflection layer may include a retarder and a polarizer. In one or more other embodiments, the anti-reflection layer may include a black matrix and color filters. The color filters may be arranged by considering a color of light emitted from each of light-emitting diodes of the image generation layer 10.

To improve transmittance of the opening area OA, the display panel 2 may include an opening 2OP passing through some of layers included in the display panel 2. The opening 2OP may include first to third openings 100P, 200P, and 300P respectively passing through the image generation layer 10, the input detection layer 20, and the optical functional layer 30. The first opening 100P defined in the image generation layer 10, the second opening 200P defined in the input detection layer 20, and the third opening 300P defined in the optical functional layer 30 may overlap each other, and may form the opening 2OP defined in the display panel 2.

The cover window 50 may be located on the optical functional layer 30. The cover window 50 may be bonded to the optical functional layer 30 through the adhesive layer 40 therebetween, the adhesive layer 40 including an optically clear 1 adhesive (OCA). The cover window 50 may cover the first opening 100P defined in the image generation layer 10, the second opening 200P defined in the input detection layer 20, and the third opening 300P defined in the optical functional layer 30.

The cover window 50 may include a glass material or a plastic material. The glass material may include Samsung Ultra Thin Glass® (Samsung Ultra Thin Glass® being a registered trademark of Samsung Display Co., Ltd., Republic of Korea). The plastic material may include polyethersulfone, polyacrylate, polyetherimide, polyethylene naphthalate, polyethylene terephthalate, polyphenylene sulfide, polyarylate, polyimide, polycarbonate, or cellulose acetate propionate.

The opening area OA may be a kind of component area (e.g., a sensor area, a camera area, a speaker area, etc.) in which the component 3 for adding various functions to the electronic device 1 is positioned.

The component 3 may include an electronic element. For example, the component 3 may be an electronic element using light or sound. For example, the electronic element may include sensors that use light, such as infrared sensors, cameras that receive light and capture images, sensors that output and detect light and sound to measure distance or recognize fingerprints, small lamps that output light, speakers that output sound, or the like. The electronic device that use light may use light in various wavelength bands, such as visible light, infrared light, and ultraviolet light. The opening area OA may correspond to an area through which light or/and sound output from the component 3 to the outside or traveling from the outside toward the electronic element may pass.

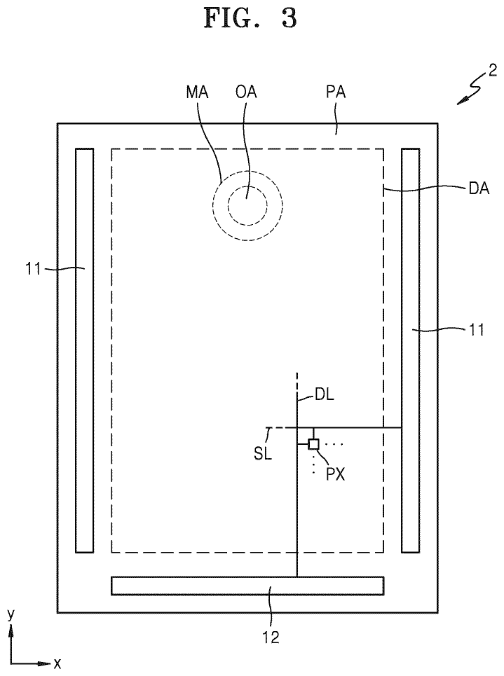

FIG. 3 is a plan view schematically illustrating the display panel 2 according to one or more embodiments.

Referring to FIG. 3, the display panel 2 may include a plurality of sub-pixels PX in the display area DA, and the display panel 2 may display an image by using light emitted from each of the sub-pixels PX. Each of the sub-pixels PX may red, green, or blue light by using a light-emitting diode. The light-emitting diode of each of the sub-pixels PX may be electrically connected to a scan line SL and a data line DL.

In the peripheral area PA, a scan driver 11 for providing a scan signal to each of the sub-pixels PX, a data driver 12 for providing a data signal to each of the sub-pixels PX, and a first main power line and a second main power line for providing a first power voltage (e.g., a driving voltage) and a second power voltage (e.g., a common voltage) may be arranged, in one or more embodiments. The scan driver 11 may be respectively arranged at opposite sides of the display area DA with the display area DA therebetween. In this case, the sub-pixel PX arranged on the left side of the opening area OA may be connected to the scan driver 11 arranged on the left side, and the sub-pixel PX arranged on the right side of the opening area OA may be connected to the scan driver 11 arranged on the right side.

The intermediate area MA may surround the opening area OA. The intermediate area MA is an area in which a display element that emits light, such as a light-emitting diode, is not arranged, and trace lines for providing signals to the sub-pixels PX provided around the opening area OA may pass through the intermediate area MA. For example, the data lines DL and/or scan lines SL may cross the display area DA, and portions of the data lines DL and/or scan lines SL may bypass the intermediate area MA along an edge of the opening area OA.

In FIG. 3, the data driver 12 is arranged adjacent to a side surface of a substrate 100. However, according to one or more other embodiments, the data driver 12 may be located on a printed circuit board electrically connected to a pad, the pad being arranged on one side of the display panel 2. The printed circuit board may be flexible, and a part of the printed circuit board may be bent to be positioned under a rear surface of the display panel 2.

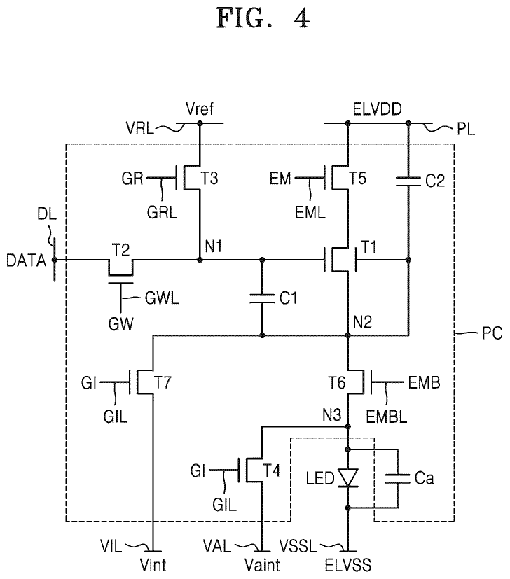

FIG. 4 is an equivalent circuit diagram schematically illustrating a light-emitting diode LED of a sub-pixel arranged in a display area, and a driving circuit PC electrically connected to the light-emitting diode LED, according to one or more embodiments.

The driving circuit PC may be electrically connected to a first gate line GWL configured to transmit a first gate signal GW, a second gate line GIL configured to transmit a second gate signal GI, a third gate line GRL configured to transmit a third gate signal GR, a fourth gate line EML configured to transmit a fourth gate signal EM, a fifth gate line EMBL configured to transmit a fifth gate signal EMB, and the data line DL configured to transmit a data signal DATA. It may be understood that each of the first gate line GWL, the second gate line GIL, the third gate line GRL, the fourth gate line EML, and the fifth gate line EMBL transfer a scan signal to a corresponding transistor. Because emission of the light-emitting diode LED is controlled by the fourth gate signal EM and the fifth gate signal EMB, the fourth gate signal EM and the fifth gate signal EMB may be referred to as emission control signals, and the fourth gate line EML and the fifth gate line EMBL may be referred to as emission control lines. The driving circuit PC may be electrically connected to a driving voltage line PL configured to transfer a driving voltage ELVDD, a reference voltage line VRL configured to transfer a reference voltage Vref, a first initialization voltage line VAL configured to transfer a first initialization voltage Vaint, and a second initialization voltage line VIL configured to transfer a second initialization voltage Vint.

In one or more embodiments, a plurality of transistors included in the driving circuit PC may be N-type oxide thin-film transistors. The oxide thin-film transistor may be a low temperature polycrystalline oxide (LTPO) in which a semiconductor layer includes an oxide. However, this is only an example, and transistors of one or more embodiments are not limited thereto. For example, the semiconductor layer included in the N-type transistor may include an inorganic semiconductor (e.g., amorphous silicon or polysilicon) or an organic semiconductor.

The driving circuit PC may include first to seventh transistors T1, T2, T3, T4, T5, T6, and T7, first and second capacitors C1 and C2, and an auxiliary capacitor Ca. The first transistor T1 may be a driving transistor for outputting a driving current corresponding to the data signal DATA, and the second to seventh transistors T2, T3, T4, T5, T6, and T7 may be switching transistors for transmitting signals. A first terminal (or first electrode) and second terminal (or second electrode) of each of the first to seventh transistors T1, T2, T3, T4, T5, T6, and T7 may be a source (or source electrode) or a drain (or drain electrode), depending on voltages at the first terminal and the second terminal. For example, depending on the voltages at the first terminal and the second terminal, the first terminal may be a drain and the second terminal may be a source, or the first terminal may be a source and the second terminal may be a drain. Hereinbelow, a node to which a first-1 gate of the first transistor T1 is connected may be defined as a first node N1, and a node to which a second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a gate (or gate electrode), a first terminal, and a second terminal connected to the second node N2. The first transistor T1 may include a first-1 gate connected to the first node N1. The first transistor T1 may further include a first-2 gate connected to the second terminal thereof. The first-1 gate and the first-2 gate may be located on different layers to face each other. For example, the first-1 gate and the 1-2 gate of the first transistor T1 may face each other with a semiconductor layer therebetween. Hereinbelow, the gate (or gate electrode) of the first transistor T1 may indicate the first-1 gate involved in turning on and off the first transistor T1.

The gate of the first transistor T1 may be connected to a second terminal of the second transistor T2, to a first terminal of the third transistor T3, and to a first capacitor C1. The first-2 gate of the first transistor T1 may be connected to a first terminal of the sixth transistor T6, to the first capacitor C1, and to a second capacitor C2. The first terminal of the first transistor T1 may be connected to the driving voltage line PL via the fifth transistor T5, and the second terminal of the first transistor T1 may be connected to a sub-pixel electrode (e.g., an anode) of the light-emitting diode LED via the sixth transistor T6. The first terminal of the first transistor T1 may be connected to a second terminal of the fifth transistor T5. The second terminal of the first transistor T1 may be connected to the first terminal of the sixth transistor T6, to the first capacitor C1, and to the second capacitor C2. The first transistor T1 may receive the data signal DATA according to a switching operation of the second transistor T2, and may control an amount of a current in a driving current flowing to the light-emitting diode LED.

The second transistor T2 may be connected to the data line DL and to the gate of the first transistor T1. The second transistor T2 may include a gate connected to the first gate line GWL, a first terminal connected to the data line DL, and a second terminal connected to the first node N1. The second terminal of the second transistor T2 may be connected to the gate of the first transistor T1, to the first terminal of the third transistor T3, and to the first capacitor C1. The second transistor T2 may be turned on according to the first gate signal GW received via the first gate line GWL, and may electrically connect the data line DL and the first node N1 to each other and transfer the data signal DATA received via the data line DL to the first node N1.

The third transistor T3 may be connected to the gate of the first transistor T1 and to the reference voltage line VRL. The third transistor T3 may include a gate connected to the third gate line GRL, to a first terminal connected to the first node N1, and to a second terminal connected to the reference voltage line VRL. The first terminal of the third transistor T3 may be connected to the gate of the first transistor T1, to the second terminal of the second transistor T2, and to the first capacitor C1. The third transistor T3 may be turned on according to the third gate signal GR received via the third gate line GRL, and may transfer the reference voltage Vref received via the reference voltage line VRL to the first node N1.

The fourth transistor T4 may be connected to the sixth transistor T6 and to the first initialization voltage line VAL. The fourth transistor T4 may be connected between the light-emitting diode LED and the first initialization voltage line VAL. The fourth transistor T4 may include a gate connected to the second gate line GIL, a first terminal connected to a third node N3, and a second terminal connected to the first initialization voltage line VAL. The first terminal of the fourth transistor T4 may be connected to a second terminal of the sixth transistor T6 and to the sub-pixel electrode of the light-emitting diode LED. The fourth transistor T4 may be turned on according to the second gate signal GI received via the second gate line GIL, and may transfer the first initialization voltage Vaint received via the first initialization voltage line VAL to the third node N3, and may initialize the sub-pixel electrode (e.g., an anode) of the light-emitting diode LED.

The fifth transistor T5 may be connected to the driving voltage line PL and to the first transistor T1. The fifth transistor T5 may include a gate connected to the fourth gate line EML, a first terminal connected to the driving voltage line PL, and a second terminal connected to the first terminal of the first transistor T1. The fifth transistor T5 may be turned on or off according to the fourth gate signal EM received via the fourth gate line EML.

The sixth transistor T6 may be connected to the first transistor T1 and to the light-emitting diode LED. The sixth transistor T6 may be connected between the second node N2 and the third node N3. The sixth transistor T6 may include a gate connected to the fifth gate line EMBL, a first terminal connected to the second node N2, and a second terminal connected to the third node N3. The first terminal of the sixth transistor T6 may be connected to the second terminal of the first transistor T1, to the first capacitor C1, and to the second capacitor C2. The second terminal of the sixth transistor T6 may be connected to the first terminal of the fourth transistor T4 and to the sub-pixel electrode of the light-emitting diode LED. The sixth transistor T6 may be turned on or off according to the fifth gate signal EMB received via the fifth gate line EMBL.

The seventh transistor T7 may be connected between the first transistor T1 and the second initialization voltage line VIL. The seventh transistor T7 may include a gate connected to the second gate line GIL, a first terminal connected to the second node N2, and a second terminal connected to the second initialization voltage line VIL. The first terminal of the seventh transistor T7 may be connected to the second terminal of the first transistor T1, to the first terminal of the sixth transistor T6, to the first capacitor C1, and to the second capacitor C2. The seventh transistor T7 may be turned on according to the second gate signal GI received via the second gate line GIL, and may transfer the second initialization voltage Vint received via the second initialization voltage line VIL to the second node N2.

The first capacitor C1 may be connected between the gate of the first transistor T1 and the second terminal of the first transistor T1. The first electrode of the first capacitor C1 may be connected to the first node N1, and the second electrode of the first capacitor C1 may be connected to the second node N2. The first electrode of the first capacitor C1 may be connected to the gate of the first transistor T1, to the second terminal of the second transistor T2, and to the first terminal of the third transistor T3. The second electrode of the first capacitor C1 may be connected to the second terminal and first-2 gate of the first transistor T1, to the second electrode of the second capacitor C2, and to the first terminal of the sixth transistor T6. The first capacitor C1 is a storage capacitor, and may store a threshold voltage of the first transistor T1 and a voltage corresponding to the data signal DATA.

When the third transistor T3 and the fifth transistor T5 are turned on, the first transistor T1 may be turned on. When a voltage at the second terminal of the first transistor T1 falls to a difference (Vref-Vth1) between the reference voltage Vref and the threshold voltage Vth1 of the first transistor T1, the first transistor T1 may be turned off, and a voltage corresponding to the threshold voltage Vth1 of the first transistor T1 may be stored in the first transistor T1, thereby compensating for the threshold voltage Vth1 of the first transistor T1.

The second capacitor C2 may be connected between the driving voltage line PL and the second node N2. The first electrode of the second capacitor C2 may be connected to the driving voltage line PL. The second electrode of the second capacitor C2 may be connected to the second terminal and first-2 gate of the first transistor T1, to the second electrode of the first capacitor C1, and to the first terminal of the sixth transistor T6.

A capacitance of each of the first capacitor C1 and the second capacitor C2 may vary depending on a color of light emitted from the light-emitting diode LED.

The auxiliary capacitor Ca may be electrically connected to the sixth transistor T6, to a sustain voltage line VSSL, and to the sub-pixel electrode of the light-emitting diode LED. The auxiliary capacitor Ca may store and maintain a voltage corresponding to a voltage difference between the sub-pixel electrode of the light-emitting diode LED and the sustain voltage line VSSL, thereby reducing or preventing the increase in black luminance when the sixth transistor T6 is turned off.

The light-emitting diode LED may be connected to the first transistor T1 through the sixth transistor T6. The light-emitting diode LED may include a sub-pixel electrode (anode) connected to the third node N3, and an opposite electrode (e.g., cathode) facing the sub-pixel electrode that may receive a common voltage ELVSS. In one or more embodiments, the opposite electrode may extend to the display area, and may be electrically connected to the sustain voltage line VSSL for providing the common voltage ELVSS. A driving current output from the first transistor T1 flows through the light-emitting diode LED according to the turned-on fifth transistor T5 and the turned-on sixth transistor T6, and the light-emitting diode LED may emit light with luminance corresponding to a size of the driving current.

In FIG. 4, the driving circuit PC includes seven transistors. However, one or more embodiments are not limited thereto. In one or more other embodiments, the driving circuit PC may include six or fewer transistors, or eight or more transistors.

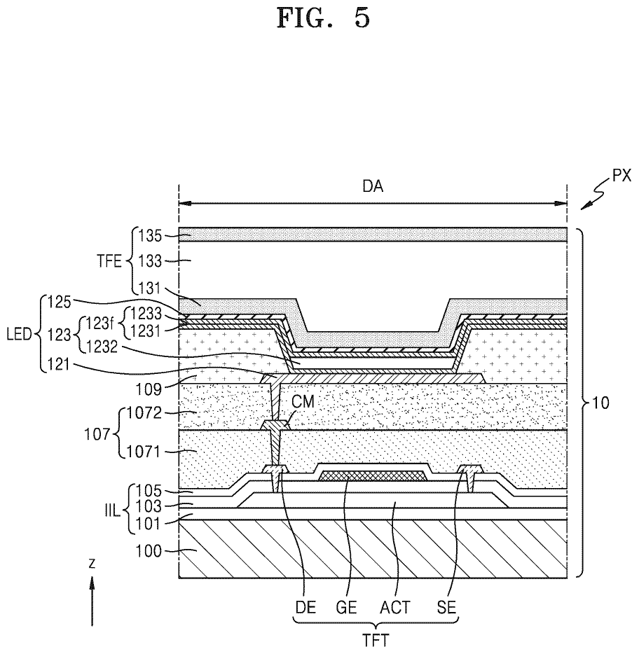

FIG. 5 is a cross-sectional view illustrating a part of the display area DA of a display panel according to one or more embodiments.

Referring to FIG. 5, the image generation layer 10 is in the display area DA. The sub-pixel PX arranged in the image generation layer 10 may include the light-emitting diode LED as a display element. In one or more embodiments, in FIG. 5, a part of the driving circuit PC described with reference to FIG. 4 is schematically shown. For example, a thin-film transistor TFT connected to the light-emitting diode LED of FIG. 5 may be a transistor connected to the light-emitting diode LED from among the transistors shown in FIG. 4 (e.g., the sixth transistor T6 or the first transistor T1).

The substrate 100 may include a glass material or polymer resin. In one or more embodiments, the substrate 100 may have an alternate stack structure of a base layer including polymer resin, and a barrier layer including an inorganic insulating material, such as silicon oxide or silicon nitride. The polymer resin may include, for example, polyethersulfone, polyarylate, polyetherimide, polyethylene naphthalate, polyethylene terephthalate, polyphenylene sulfide, polyimide, polycarbonate, cellulose triacetate, or cellulose acetate propionate.

A buffer layer 101 may be located on the substrate 100 (as used herein, “located on” may mean “above”). The buffer layer 101 may planarize and protect an upper surface of the substrate 100. The buffer layer 101 may include an inorganic insulating material, such as silicon oxide (SiOₓ), silicon nitride (SiNₓ), and/or silicon oxynitride (SiOₓN_{y}), and may be a single-layer or multi-layer structure of the materials described above. In one or more embodiments, a barrier layer may be further between the substrate 100 and the buffer layer 101. The barrier layer may include a material similar to that of the buffer layer 101.

The thin-film transistor TFT may be located on the buffer layer 101. As described above, the thin-film transistor TFT may be a brief illustration of a part of the driving circuit PC of FIG. 4 (e.g., the first transistor T1 or the sixth transistor T6). The thin-film transistor TFT may include an activation layer ACT, a gate electrode GE, a source electrode SE, and a drain electrode DE. The gate electrode GE may correspond to the gate described above with reference to FIG. 4. The source electrode SE and the drain electrode DE may correspond to the first terminal (or first electrode) and the second terminal (or second electrode) described above with reference to FIG. 4.

The activation layer ACT may be located on the buffer layer 101, and may include a drain region overlapping the drain electrode DE, a source region overlapping the source electrode SE, and a channel region between the drain region and the source region. The source region and drain region of the activation layer ACT may be areas doped with impurities.

A gate-insulating layer 103 may be located on the activation layer ACT. The gate-insulating layer 103 may include an inorganic material including an oxide or nitride. For example, the gate-insulating layer 103 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multi-layer structure of the materials described above.

The gate electrode GE may be located on the gate-insulating layer 103. The gate electrode GE may at least partially overlap the activation layer ACT. For example, the gate electrode GE may overlap the channel region of the activation layer ACT. The gate electrode GE may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may have a single-layer or multi-layer structure of the materials described above.

An interlayer insulating layer 105 may cover the gate electrode GE. The interlayer insulating layer 105 may include an inorganic material including an oxide or nitride. For example, the interlayer insulating layer 105 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multi-layer structure of the materials described above.

The gate-insulating layer 103 and the interlayer insulating layer 105 may include a contact hole that overlaps the source region and drain region of the activation layer ACT. The source electrode SE and the drain electrode DE may be located on the interlayer insulating layer 105. The source electrode SE may be arranged to overlap the source region of the activation layer ACT, and the drain electrode DE may be arranged to overlap the drain region of the activation layer ACT. The source electrode SE and the drain electrode DE may be connected to the activation layer ACT through respective contact holes formed in the gate-insulating layer 103 and the interlayer insulating layer 105.

An organic insulating layer 107 may cover the gate-insulating layer 103, an inorganic insulating layer IIL including the interlayer insulating layer 105, and the thin-film transistor TFT. The organic insulating layer 107 may include a first organic insulating layer 1071 located on the inorganic insulating layer IIL, and a second organic insulating layer 1072 located on the first organic insulating layer 1071.

The first organic insulating layer 1071 may include a contact hole overlapping the drain electrode DE. A contact metal CM may be located on an upper surface of the first organic insulating layer 1071, and may be electrically connected to the drain electrode DE through the contact hole defined in the first organic insulating layer 1071. The second organic insulating layer 1072 may include a contact hole that overlaps the contact metal CM. A sub-pixel electrode 121 may be located on an upper surface of the second organic insulating layer 1072, and may be electrically connected to the contact metal CM through the contact hole defined in the second organic insulating layer 1072. Accordingly, the sub-pixel electrode 121 may be electrically connected to the drain electrode DE of the thin-film transistor TFT through the contact metal CM.

In FIG. 5, two organic insulating layers (e.g., the first organic insulating layer 1071 and the second organic insulating layer 1072) and one contact metal CM are shown. However, one or more embodiments are not limited thereto. In one or more other embodiments, N organic insulating layers (N may be a natural number of 3 or more) and (N-1) contact metals may be provided. Alternatively, in one or more other embodiments, an organic insulating layer may be a single layer, and the contact metal may be omitted.

The organic insulating layer 107, such as the first organic insulating layer 1071 and the second organic insulating layer 1072, may include benzocyclobutene, polyimide, hexamethyldisiloxane, polymethylmethacrylate, general-purpose polymers, such as polystyrene, polymer derivatives having a phenol-based group, acryl-based polymers, imide-based polymers, aryl ether-based polymers, amide-based polymers, fluorine-based polymers, p-xylene-based polymers, or vinyl alcohol-based polymers, and may have a single-layer or multi-layer structure of the materials described above. In one or more embodiments, the first organic insulating layer 1071 and the second organic insulating layer 1072 may include a same material. In one or more embodiments, the first organic insulating layer 1071 and the second organic insulating layer 1072 may include different materials. In one or more embodiments, the first organic insulating layer 1071 and/or the second organic insulating layer 1072 may include a plurality of layers including different materials from each other.

The sub-pixel electrode 121 may be located on an upper surface of the organic insulating layer 107, for example, on an upper surface of the second organic insulating layer 1072. As described above, the sub-pixel electrode 121 may be electrically connected to the contact metal CM through a contact hole defined in the second organic insulating layer 1072.

The sub-pixel electrode 121 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 121 may include a reflective film including Ag, Mg, Al, Pt, Pd, Au, Ni, Nd, Ir, Cr, or a compound thereof. However, a configuration and material of the sub-pixel electrode 121 are not limited thereto, and various modifications may be made.

A pixel-defining layer 109 may be located on the organic insulating layer 107, for example, on an upper surface of the second organic insulating layer 1072. The pixel-defining layer 109 may cover an edge (or edge area) of the sub-pixel electrode 121. In other words, the pixel-defining layer 109 may be opened to expose a part of a central portion of the sub-pixel electrode 121. A size and shape of an emission area of the light-emitting diode LED may be determined by an opening.

An intermediate layer 123 may be located on the sub-pixel electrode 121. The intermediate layer 123 may include a functional layer 123f located on the pixel-defining layer 109, and an emission layer 1232 arranged within the opening defined in the pixel-defining layer 109. The functional layer 123f may include a first functional layer 1231 located on the pixel-defining layer 109, and a second functional layer 1233 located on the first functional layer 1231. In one or more embodiments, the first functional layer 1231 may be located on the pixel-defining layer 109, the emission layer 1232 may be located in the opening defined in the pixel-defining layer 109 on the first functional layer 1231, and the second functional layer 1233 may be located on the first functional layer 1231 to cover the emission layer 1232. In other words, the emission layer 1232 may be arranged in the opening defined in the pixel-defining layer 109, and may be between the first functional layer 1231 and the second functional layer 1233.

The emission layer 1232 may include an organic emission layer including a low-molecular or polymer material. The first functional layer 1231 may include an electron transport layer (ETL) and/or an electron injection layer (EIL). The second functional layer 1233 may include a hole transport layer (HTL) and/or a hole injection layer (HIL). In some embodiments, the first functional layer 1231 or the second functional layer 1233 may be omitted. In some embodiments, positions of the first functional layer 1231 and the second functional layer 1233 may be exchanged.

An opposite electrode 125 may be located on the intermediate layer 123. For example, the opposite electrode may be located on the second functional layer 1233. The opposite electrode 125 may be arranged to entirely cover the intermediate layer 123. The opposite electrode 125 may include a conductive material with a low work function. For example, the opposite electrode 125 may include a semi-transparent or transparent layer including Ag, Mg, Al, Pt, Pd, Au, Nl, Nd, Ir, Cr, Li, Ca, or an alloy thereof. Alternatively, the opposite electrode 125 may further include a layer including ITO, IZO, ZnO, or In₂O₃, on the (semi-) transparent layer including the materials described above.

A thin-film encapsulation layer TFE may be located on the opposite electrode 125, and may entirely cover the light-emitting diode LED. The thin-film encapsulation layer TFE may include at least one inorganic layer and at least one organic layer. In one or more embodiments, the thin-film encapsulation layer TFE may include a first inorganic encapsulation layer 131 and a second inorganic encapsulation layer 135, and may include an organic encapsulation layer 133 between the first inorganic encapsulation layer 131 and the second inorganic encapsulation layer 135.

The first inorganic encapsulation layer 131 and the second inorganic encapsulation layer 135 may include one or more inorganic insulating material, such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The organic encapsulation layer 133 may include a polymer-based material. The polymer-based material may include silicon-based resin, acryl-based resin, epoxy-based resin, polyimide, polyethylene, or the like.

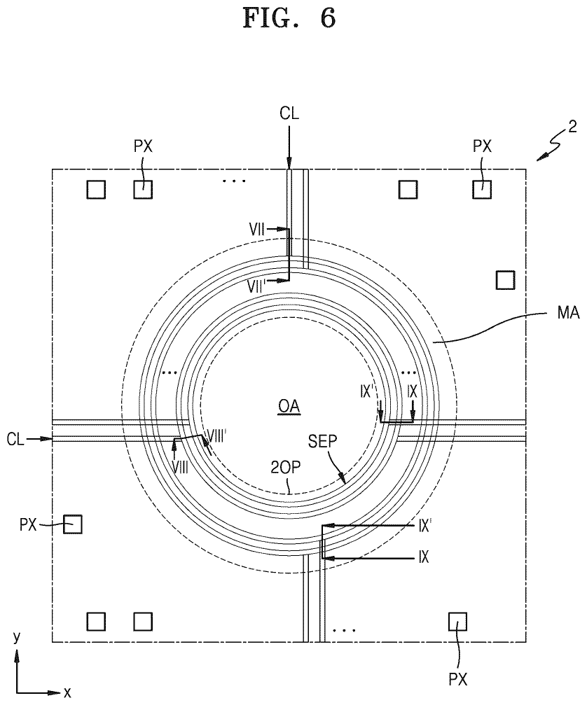

FIG. 6 is a plan view illustrating a part of the display panel 2 according to one or more embodiments.

FIG. 6 shows the opening area OA, the intermediate area MA, and the display area DA of the display panel 2. The sub-pixels PX may be arranged in the display area DA. The sub-pixels PX may be arranged to surround the opening area OA and the intermediate area MA in the display area DA (e.g., in plan view). The sub-pixels PX is a minimum area where light is emitted, and may emit light through a display element, for example, a light-emitting diode. A position of the sub-pixel PX may correspond to a position of the light-emitting diode. The sub-pixel PX being located in the display area DA may indicate that the light-emitting diode is arranged in the display area DA.

In a plan view, the sub-pixels PX and/or light-emitting diodes adjacent to the opening area OA may be arranged apart from each other with respect to the opening area OA. The sub-pixels PX and/or light-emitting diodes may be arranged vertically apart from each other with respect to the opening area OA, or may be arranged horizontally apart from each other with respect to the opening area OA. Separators SEP may be arranged apart from each other in the intermediate area MA. In other words, the separators SEP may be arranged apart from each other between the display area DA and the opening area OA, or between the display area DA and the opening 2OP. In a plan view (e.g., when viewed from a direction perpendicular to the upper surface of the substrate), each of the separators SEP may surround the opening area OA or the opening 2OP. In a plan view, each of the separators SEP may have a closed loop shape. In one or more embodiments, in a plan view, the separators SEP may have a concentric circular shape with the opening area OA or the opening 2OP. In this case, a diameter of the separator SEP may be greater than a diameter of the opening area OA or opening 2OP. As described above, the separator SEP may include a conductive material.

A plurality of conductive lines CL may be arranged in the display area DA and the intermediate area MA. In other words, the conductive lines CL may extend across the display area DA and the intermediate area MA. The conductive lines CL may include conductive lines CL extending in different directions (e.g., the conductive line CL extending in an x direction and the conductive line CL extending in a y direction). In one or more embodiments, the plurality of conductive lines CL extending in the x direction may be arranged apart from each other in the y direction. The plurality of conductive lines CL extending in the y direction may be arranged apart from each other in the x direction.

The conductive lines CL may include various lines arranged in the display panel 2, such as scan lines, data lines, and/or voltage lines. For example, referring to FIG. 6 together with FIG. 4, the conductive lines CL may include at least one of the first gate line GWL, the second gate line GIL, the third gate line GRL, the fourth gate line EML, the fifth gate line EMBL, the data line DL, the driving voltage line PL, the reference voltage line VRL, the first initialization voltage line VAL, and/or the second initialization voltage line VIL.

The conductive lines CL may be connected to the separators SEP in the intermediate area MA. For example, each of the conductive lines CL may be connected to a corresponding separator SEP in the intermediate area MA. In one or more embodiments, one of the conductive lines CL arranged on the left side (or a −x direction) of the opening area OA, and one of the conductive lines CL arranged on the right side (or a +x direction) of the opening area OA, may be connected to a same separator SEP. Through this, the conductive line CL on the left side of the opening area OA and the conductive line CL on the right side of the opening area OA may be electrically connected to each other by the separator SEP in the intermediate area MA. The conductive line CL may transfer current between the left and right sides of the opening area OA through the separator SEP. In other words, the separator SEP may act as an electrical path through which current may be transferred within the intermediate area MA.

Because the plurality of separators SEP may be provided in the intermediate area MA, and because each of the separators SEP may be spaced apart from each other, it may be understood that in the intermediate area MA, there are as many electrical paths as there are the separators SEP spaced apart from each other. Each of the conductive lines CL may obtain an electrical path bypassing the opening area OA by using the separator SEP. In other words, the separators SEP may be used as electrical paths through which some of various lines present in the display panel 2 may bypass the opening area OA.

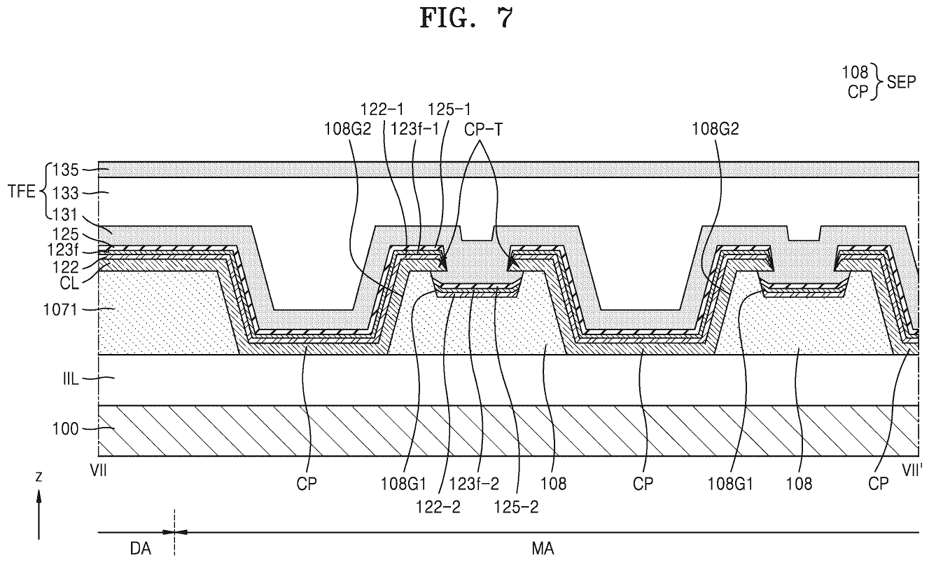

FIG. 7 is a cross-sectional view of a part of the display panel 2 of FIG. 6, taken along the line VII-VII′, according to one or more embodiments.

Referring to FIG. 7, the inorganic insulating layer IIL may be located on the substrate 100. For example, the inorganic insulating layer IIL may include the buffer layer 101 (see FIG. 5), the gate-insulating layer 103 (see FIG. 5), and the interlayer insulating layer 105 (see FIG. 5) described above. The plurality of separators SEP may be located on the inorganic insulating layer IIL. The separator SEP may separate the functional layer 123f and the opposite electrode 125 into a plurality of portions, which is described below. The separator SEP may include an organic pattern layer 108 and a conductive pattern layer CP.

The organic pattern layer 108 may be located on the inorganic insulating layer IIL. For example, the organic pattern layer 108 may be located on an upper surface of the inorganic insulating layer IIL. In one or more embodiments, the organic pattern layer 108 and the first organic insulating layer 1071 may include a same material. In one or more embodiments, the organic pattern layer 108 and the first organic insulating layer 1071 may be concurrently or substantially simultaneously formed.

The organic pattern layer 108 may include a first groove 108G1 and a second groove 108G2. The first groove 108G1 and second groove 108G2 of the organic pattern layer 108 may be alternately arranged in one direction (e.g., a direction perpendicular to a Z axis). For example, the first groove 108G1 may be positioned between two adjacent second grooves 108G2, and the second groove 108G2 may be positioned between two adjacent first grooves 108G1. In one or more embodiments, the first groove 108G1 may not pass through the organic pattern layer 108 (e.g., the first groove 108G1 may be defined by the organic pattern layer 108). In one or more embodiments, the first groove 108G1 may include a side surface angled to the Z axis. In other words, the side surface of the first groove 108G1 may be tapered with respect to the upper surface of the inorganic insulating layer IIL. In one or more embodiments, the second groove 108G2 may pass through the organic pattern layer 108. In one or more embodiments, the second groove 108G2 may include a side surface angled to the Z axis. In other words, the side surface of the second groove 108G2 may be tapered with respect to the inorganic insulating layer IIL. In one or more embodiments, an angle at which the side surface of the first groove 108G1 is inclined with respect to the Z axis and an angle at which the side surface of the second groove 108G2 is inclined with respect to the Z axis may be equal to each other. However, one or more embodiments are not necessarily limited thereto, and the side surfaces of the first groove 108G1 and second groove 108G2 may be parallel to the Z axis.

The conductive pattern layer CP may be located on the organic pattern layer 108. The conductive pattern layer CP may include a conductive material. In one or more embodiments, the conductive pattern layer CP and the contact metal CM (see FIG. 5) may include a same material. In one or more embodiments, the conductive pattern layer CP and the contact metal CM (see FIG. 5) may be formed concurrently or substantially simultaneously.

A part of the conductive pattern layer CP may be arranged in the second groove 108G2 of the organic pattern layer 108. In one or more embodiments, the conductive pattern layer CP may be in direct contact with the upper surface of the inorganic insulating layer IIL within the second groove 108G2. In one or more embodiments, the conductive pattern layer CP may cover the side surface of the organic pattern layer 108 and the upper surface of the inorganic insulating layer IIL, which are in contact with the second groove 108G2.

A part of the conductive pattern layer CP may protrude from an upper surface of the organic pattern layer 108 toward a center of the first groove 108G1 (e.g., in plan view). For example, a part of the conductive pattern layer CP may be located on the upper surface of the organic pattern layer 108, and may protrude from an edge of the upper surface of the organic pattern layer 108 in contact with the first groove 108G1. In other words, the conductive pattern layer CP may include a tip CP-T structure that protrudes toward the center of the first groove 108G1 from the edge of the organic pattern layer 108.

The conductive line CL may be arranged across the display area DA and the intermediate area MA. For example, a part of the conductive line CL may be positioned in the display area DA, and another part of the conductive line CL may be positioned in the intermediate area MA. In one or more embodiments, the conductive line CL and the conductive pattern layer CP may include a same material. In one or more embodiments, the conductive line CL and the contact metal CM (see FIG. 5) may include a same material. In one or more embodiments, the conductive line CL and the conductive pattern layer CP may be integrally formed. Accordingly, the conductive line CL and the conductive pattern layer CP may be electrically connected to each other. In one or more embodiments, the conductive line CL, the conductive pattern layer CP, and the contact metal CM (see FIG. 5) may be formed concurrently or substantially simultaneously. In one or more embodiments, the first organic insulating layer 1071 and the organic pattern layer 108 may be concurrently or substantially simultaneously formed, and the contact metal CM (see FIG. 5), the conductive line CL, and the conductive pattern layer CP may be concurrently or substantially simultaneously formed. In this case, the contact metal CM (see FIG. 5) and the conductive line CL may be located on the first organic insulating layer 1071, and the conductive pattern layer CP may be positioned on the organic pattern layer 108.

In one or more embodiments, the conductive line CL may be the data line DL (see FIG. 3) described above. In one or more embodiments, the data line DL (see FIG. 3), the conductive line CL, and the conductive pattern layer CP may be integrally formed. Accordingly, the data line DL (see FIG. 3) and the conductive pattern layer CP may be electrically connected to each other.

A cover layer 122 may be located on the conductive pattern layer CP. The cover layer 122 may include a conductive material. In one or more embodiments, the cover layer 122 and the sub-pixel electrode 121 (see FIG. 5) may include a same material. In one or more embodiments, the cover layer 122 and the sub-pixel electrode 121 (see FIG. 5) may be concurrently or substantially simultaneously formed.

A part of the cover layer 122 may be located on the conductive line CL. Another part of the cover layer 122 may be located on the conductive pattern layer CP within the second groove 108G2 of the organic pattern layer 108. Another part of the cover layer 122 (e.g., a first portion 122-1 of the cover layer 122) may be located on the tip CP-T of the conductive pattern layer CP. In one or more embodiments, the first portion 122-1 of the cover layer 122 may cover an upper surface of the tip CP-T of the conductive pattern layer CP. Another part of the cover layer 122 (e.g., a second portion 122-2 of the cover layer 122) may be arranged in the first groove 108G1 of the organic pattern layer 108. In one or more embodiments, the second portion 122-2 of the cover layer 122 may cover an upper surface of a portion of the organic pattern layer 108 in which the first groove 108G1 is formed. In one or more embodiments, the second portion 122-2 of the cover layer 122 may be in contact of a side surface of the portion of the organic pattern layer 108 in which the first groove 108G1 is formed. The first portion 122-1 and the second portion 122-2 of the cover layer 122 may be apart from each other by the tip CP-T of the conductive pattern layer CP.

The functional layer 123f may be located on the cover layer 122. A part of the functional layer 123f may be located on the cover layer 122 within the second groove 108G2. Another part of the functional layer 123f (e.g., a first portion 123f-1 of the functional layer 123f) may be located on the first portion 122-1 of the cover layer 122. In one or more embodiments, the first portion 123f-1 of the functional layer 123f may cover an upper portion of the first portion 122-1 of the cover layer 122. Another part of the functional layer 123f (e.g., a second portion 123f-2 of the functional layer 123f) may be located on the second portion 122-2 of the cover layer 122. Accordingly, the second portion 123f-2 of the functional layer 123f may be arranged in the first groove 108G1 of the organic pattern layer 108. In one or more embodiments, the second portion 123f-2 of the functional layer 123f may cover an upper surface of the second portion 122-2 of the cover layer 122. In one or more embodiments, the second portion 123f-2 of the functional layer 123f may be in contact of a side surface of the portion of the organic pattern layer 108 in which the first groove 108G1 is formed. The first portion 123f-1 and the second portion 123f-2 of the functional layer 123f may be apart from each other by the tip CP-T of the conductive pattern layer CP.

The opposite electrode 125 may be located on the functional layer 123f. A part of the opposite electrode 125 may be located on the functional layer 123f within the second groove 108G2. Another part of the opposite electrode 125 (e.g., a first portion 125-1 of the opposite electrode 125) may be located on the first portion 123f-1 of the functional layer 123f. In one or more embodiments, the first portion 125-1 of the opposite electrode 125 may cover an upper surface of the first portion 123f-1 of the functional layer 123f. Another part of the opposite electrode 125 (e.g., a second portion 125-2 of the opposite electrode 125) may be located on the second portion 123f-2 of the functional layer 123f. Accordingly, the second portion 125-2 of the opposite electrode 125 may be arranged in the first groove 108G1 of the organic pattern layer 108. In one or more embodiments, the second portion 125-2 of the opposite electrode 125 may cover an upper surface of the second portion 123f-2 of the functional layer 123f. In one or more embodiments, the second portion 125-2 of the opposite electrode 125 may be in contact of a side surface of the portion of the organic pattern layer 108 in which the first groove 108G1 is formed. The first portion 125-1 and the second portion 125-2 of the opposite electrode 125 may be separated from each other due to the tip CP-T of the conductive pattern layer CP.

The thin-film encapsulation layer TFE may entirely cover the opposite electrode 125. For example, the first inorganic encapsulation layer 131 may entirely cover the opposite electrode 125. A part of the first inorganic encapsulation layer 131 may be arranged in the first groove 108G1. A part of the first inorganic encapsulation layer 131 may be arranged in the second groove 108G2. In the first groove 108G1, the first inorganic encapsulation layer 131 may be in contact with the side surface of the organic pattern layer 108 in which the first groove 108G1 is formed.

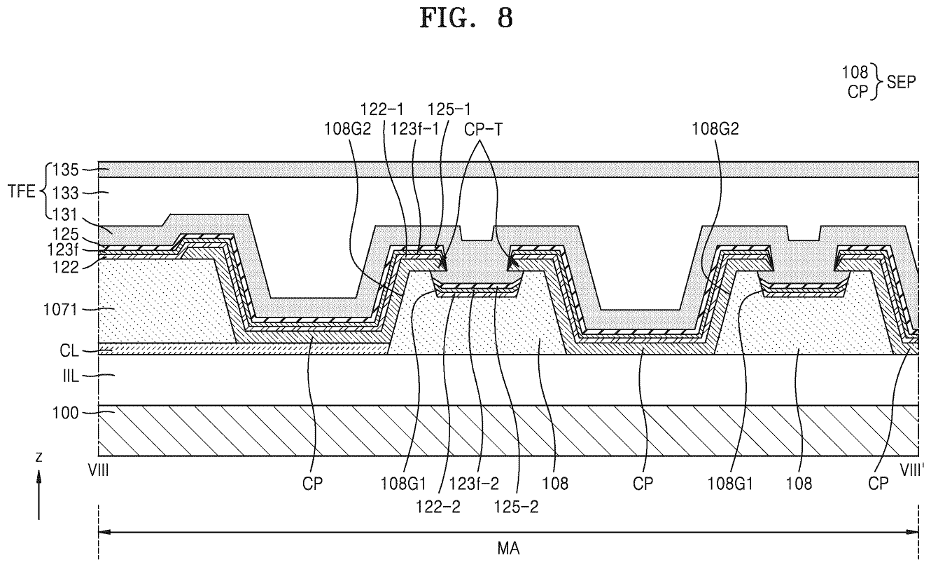

FIG. 8 is a cross-sectional view of a part of the display panel 2 of FIG. 6, taken along the line VIII-VIII′, according to one or more embodiments.

From among features of the embodiments corresponding to FIG. 8, features other than those described below are substantially the same as the embodiments corresponding to FIG. 7.

Referring to FIG. 8, the conductive line CL may be located on the inorganic insulating layer IIL. For example, the conductive line CL may be located between the first organic insulating layer 1071 and the inorganic insulating layer IIL. A part of the conductive line CL may overlap the second groove 108G2 of the organic pattern layer 108. In one or more embodiments, the conductive line CL may be in direct contact with a part of the conductive pattern layer CP arranged in the second groove 108G2. For example, the upper surface of the conductive line CL and a lower surface of the conductive pattern layer CP may be in direct contact with each other. Accordingly, the conductive line CL may be electrically connected to the conductive pattern layer CP.

In one or more embodiments, the conductive line CL may include the source electrode SE (see FIG. 5) and/or the drain electrode DE (see FIG. 5). In one or more embodiments, the conductive line CL may be formed concurrently or substantially simultaneously with the source electrode SE (see FIG. 5) and/or the drain electrode DE (see FIG. 5).

In one or more embodiments, the conductive line CL may be the scan line SL (see FIG. 3) described above. In one or more embodiments, the scan line SL (see FIG. 3), the conductive line CL, and the conductive pattern layer CP may be integrally formed.

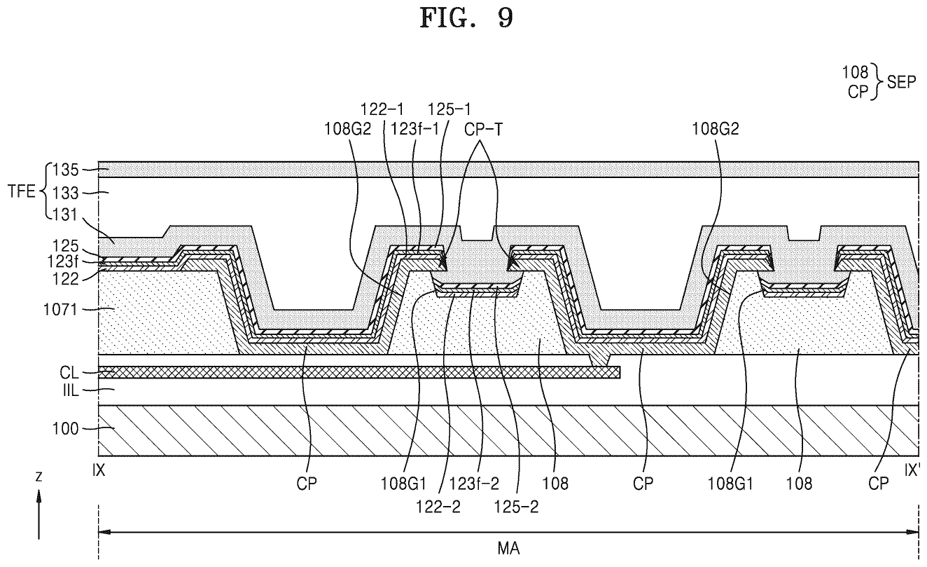

FIG. 9 is a cross-sectional view of a part of the display panel 2 of FIG. 6, taken along the line IX-IX′, according to one or more embodiments.

From among features of the embodiments corresponding to FIG. 9, features other than those described below are substantially the same as the embodiments corresponding to FIG. 7.

Referring to FIG. 9, the conductive line CL may be arranged in the inorganic insulating layer IIL. For example, a part of the inorganic insulating layer IIL may be between the conductive line CL and the conductive pattern layer CP, or between the conductive line CL and the organic pattern layer 108. In other words, an upper surface of the conductive line CL may be spaced apart from a lower surface of the organic pattern layer 108. The conductive line CL may overlap the second groove 108G2 of the organic pattern layer 108. In an area of the organic pattern layer 108 overlapping the second groove 108G2, the inorganic insulating layer IIL between the conductive line CL and the conductive pattern layer CP may include a contact hole. The conductive line CL and the conductive pattern layer CP may be in direct contact with each other through the contact hole. Through this, the conductive line CL may be electrically connected to the conductive pattern layer CP.

In one or more embodiments, the conductive line CL may include a same material as the gate electrode GE (see FIG. 5). In one or more embodiments, the conductive line CL may be formed concurrently or substantially simultaneously with the gate electrode GE (see FIG. 5).

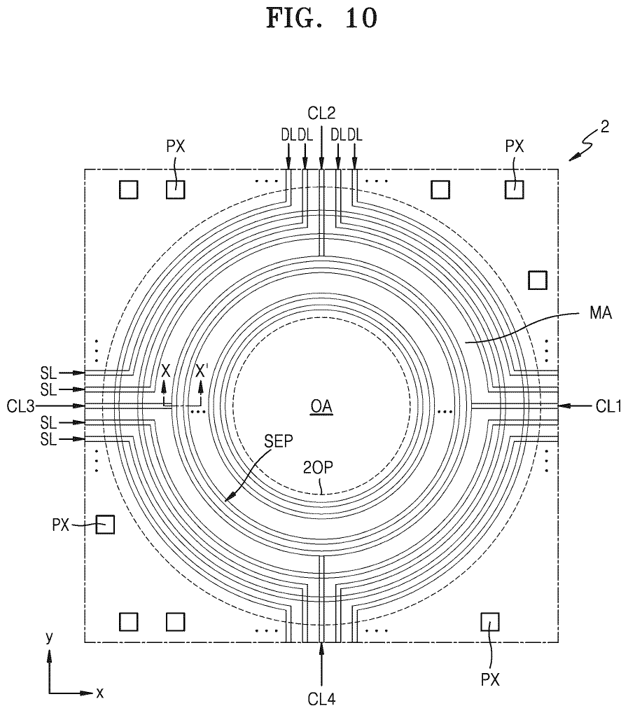

FIG. 10 is a plan view illustrating a part of the display panel 2 according to one or more other embodiments.

From among features of the embodiments corresponding to FIG. 10, features other than those described below are substantially the same as the embodiments corresponding to FIG. 6.

Referring to FIG. 10, some of each of the scan lines SL extending in the x axis and the data lines DL extending in the y axis may be arranged in the intermediate area MA. For example, the scan lines SL and the data lines DL may be arranged in the display area DA and the intermediate area MA. Each of the scan lines SL and the data lines DL may bypass the opening area OA or the opening 2OP so as not to be arranged in the opening area OA. For example, at least one of the scan lines SL may extend along the x axis and then along a path that forms a concentric circular shape with the opening area OA in the intermediate area MA, and may extend along the x axis again and may bypass the opening area OA. Similarly, at least one of the data lines DL may extend along the y axis and then along a path that forms a concentric circular shape with the opening area OA in the intermediate area MA, and may extend along the y axis again and may bypass the opening area OA.

A plurality of conductive lines may be arranged in the display area DA and the intermediate area MA. In one or more embodiments, a first conductive line CL1 may be positioned on the right side (or the +x side) of the opening area OA and may extend along the x axis. In one or more embodiments, a second conductive line CL2 may be positioned above (or on a +y side) the opening area OA and may extend along the y axis. In one or more embodiments, a third conductive line CL3 may be positioned on the left side (or a −x side) of the opening area OA and may extend along the x axis. In one or more embodiments, a fourth conductive line CL4 may be positioned under (or on a −y side) the opening area OA and may extend along the y axis. In one or more embodiments, the display panel 2 may include at least one of the first conductive line CL1 to the fourth conductive line CL4.

The scan lines SL may be located over (or on the +y side) or under (or on the −y side) the first conductive line CL1 and the third conductive line CL3. The scan lines SL located over (or on the +y side) the first conductive line CL1 and the third conductive line CL3 may extend along an area positioned over (or on the +y side) the opening area OA, and may bypass the opening area OA. The scan lines SL located under (or on the −y side) the first conductive line CL1 and the third conductive line CL3 may extend along an area positioned under (or on the −y side) the opening area OA and may bypass the opening area OA.

The data lines DL may be arranged on the right side (or the +x side) or the left side (or the −x side) of the second conductive line CL2 and the fourth conductive line CL4. The data lines DL located on the right side (or on the +x side) of the second conductive line CL2 and the fourth conductive line CL4 may extend along an area positioned on the right side (or the +x side) of the opening area OA, and may bypass the opening area OA. The data lines DL located on the left side (or on the −x side) of the second conductive line CL2 and the fourth conductive line CL4 may extend along an area positioned on the left side (or the −x side) of the opening area OA, and may bypass the opening area OA.

The plurality of separators SEP may be arranged within the intermediate area MA. In one or more embodiments, the separators SEP may be between the opening area OA and the scan lines SL, and between the opening area OA and the data lines DL. In one or more embodiments, in a plan view, the separators SEP may surround the opening area OA. Each of the separators SEP may have a closed loop shape. In one or more embodiments, in a plan view, the separators SEP may have a concentric circular shape with the opening area OA or the opening 2OP. In one or more embodiments, at least one of the first conductive line CL1 to the fourth conductive line CL4 may be connected to at least one of the separators SEP. In FIG. 10, a case where the first conductive line CL1 to the fourth conductive line CL4 are connected to the separator SEP arranged on an outermost side. In one or more other embodiments, only some of the first conductive line CL1 to the fourth conductive line CL4 may be connected to the separator SEP. In one or more other embodiments, each of the first conductive line CL1 to the fourth conductive line CL4 may be connected to different separators SEP, respectively.

In one or more embodiments, the plurality of separators SEP may be respectively electrically connected to each other. For example, the separators SEP may be electrically connected to each other through a conductive layer, which is described below. The separators SEP are electrically connected to each other to act as a single electrical path within the intermediate area MA. For example, the separators SEP, the first conductive line CL1, the second conductive line CL2, the third conductive line CL3, and the fourth conductive line CL4 may all be respectively electrically connected to each other. In other words, the first conductive line CL1 to the fourth conductive line CL4 may be electrically connected to each other through the separators SEP. Because the separators SEP are electrically connected to each other, the first conductive line CL1 to the fourth conductive line CL4 may be electrically connected to each other even though the first conductive line CL1 to the fourth conductive line CL4 are electrically connected to different separators SEP, respectively. The separators SEP are connected to each other to act as a single electrical path, and thus may be used as an electrical path bypassing the opening area OA in the intermediate area MA, and the resistance thereof may be reduced.

In one or more embodiments, the first conductive line CL1 to the fourth conductive line CL4 may be voltage lines. For example, at least one of the first conductive line CL1 to the fourth conductive line CL4 may be the sustain voltage line VSSL (see FIG. 4) for supplying the common voltage ELVSS (see FIG. 4) to the opposite electrode (cathode) of the light-emitting diode. Using the structure of the separators SEP that form a single electrical path described above, when the sustain voltage line VSSL (see FIG. 4) is arranged to supply the common voltage ELVSS (see FIG. 4) to the light-emitting diode, resistance acting within the sustain voltage line VSSL (see FIG. 4) may be reduced compared to when the sustain voltage line VSSL (see FIG. 4) is arranged to bypass the intermediate area MA and the opening area OA concurrently or substantially simultaneously. However, one or more embodiments are not limited to a case where the first conductive line CL1 to the fourth conductive line CL4 are voltage lines.

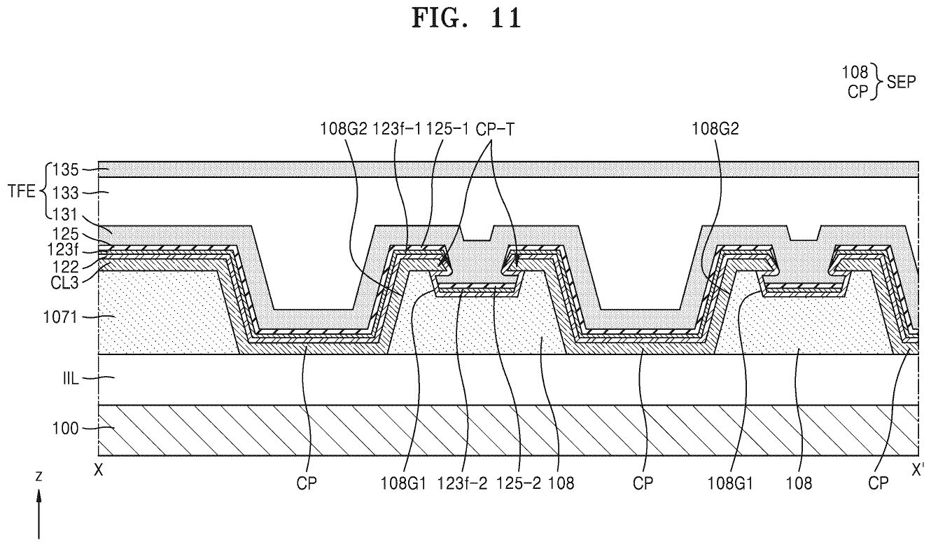

Hereinbelow, various embodiments of a structure in which the third conductive line CL3 is connected to the separator SEP, and a structure in which each of the separators SEP are electrically connected to each other are described with reference to FIGS. 11 to 18. Although a case of the third conductive line CL3 is mainly described below, this is for convenience of description, and structures of embodiments described below may be similarly applied to the first conductive line CL1, the second conductive line CL2, and the fourth conductive line CL4.

FIG. 11 is an example of a cross-sectional view of a part of the display panel 2 of FIG. 10, taken along the line X-X′, according to one or more embodiments.

From among features of the embodiments corresponding to FIG. 11, features other than those described below are substantially the same as the embodiments corresponding to FIG. 7.

Referring to FIG. 11, the cover layer 122 may be located on the organic pattern layer 108 and the cover layer 122 and may be integrally formed. Accordingly, the cover layer 122 may entirely over the organic pattern layer 108 and the conductive pattern layer CP. For example, the cover layer 122 may continuously extend to cover the upper surface of the conductive pattern layer CP, to cover side and lower surfaces of the tip CP-T of the conductive pattern layer CP, and to cover, or define a portion of, the first groove 108G1 (e.g., to cover a portion of the organic pattern layer in the first groove 108G1). Accordingly, the cover layer 122 may cover the side and upper surfaces of the organic pattern layer 108 in which the first groove 108G1 is formed. Because the cover layer 122 covers the first groove 108G1, the second portion 123f-2 of the functional layer 123f and the second portion 125-2 of the opposite electrode 125 may be spaced apart from the side surface of the organic pattern layer 108 in which the first groove 108G1 is formed.

The cover layer 122 and the conductive pattern layer CP may include a conductive material. Accordingly, two tips CP-T of the conductive pattern layer CP spaced apart from each other with the first groove 108G1 therebetween (e.g., in plan view) may be electrically connected to each other by the cover layer 122. Because the cover layer 122 extends continuously, each of portions of the conductive pattern layer CP arranged apart from each other may all be electrically connected to each other. Accordingly, each of the separators SEP may be electrically connected to each other, and may form a single electrical path.

The third conductive line CL3 may be located on the first organic insulating layer 1071. In one or more embodiments, the third conductive line CL3 and the conductive pattern layer CP may include a same material. In one or more embodiments, the third conductive line CL3 and the conductive pattern layer CP may be integrally formed. Accordingly, the third conductive line CL3, the conductive pattern layer CP, and the cover layer 122 may be electrically connected to each other.

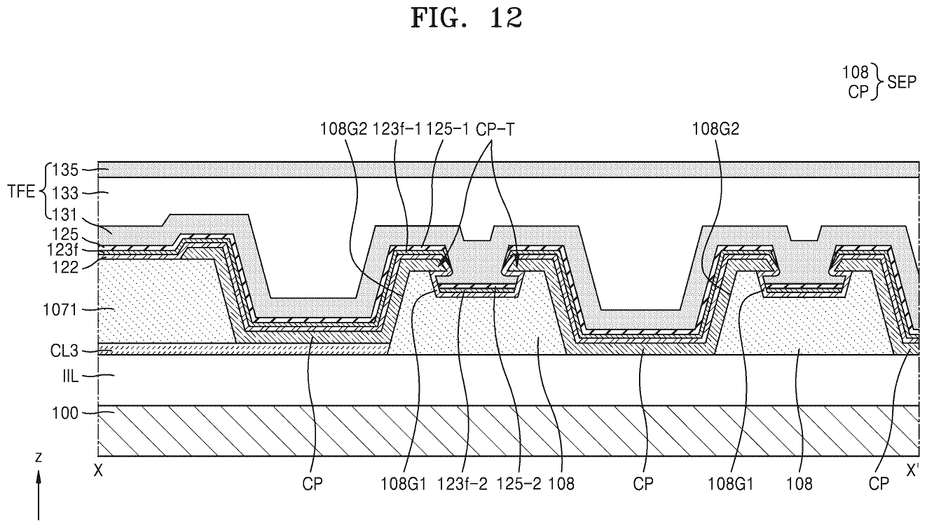

FIG. 12 is an example of a cross-sectional view of a part of the display panel 2 of FIG. 10, taken along the line X-X′, according to one or more embodiments.

From among features of the embodiments corresponding to FIG. 12, features other than those described below are substantially the same as the embodiments corresponding to FIG. 11.

Referring to FIG. 12, the third conductive line CL3 may be located on the inorganic insulating layer IIL. For example, the third conductive line CL3 may be located between the first organic insulating layer 1071 and the inorganic insulating layer IIL. A part of the third conductive line CL3 may overlap the second groove 108G2 of the organic pattern layer 108. In one or more embodiments, the third conductive line CL3 may be in direct contact with a part of the conductive pattern layer CP arranged in the second groove 108G2. For example, an upper surface of the third conductive line CL3 and the lower surface of the conductive pattern layer CP may be in direct contact with each other. Accordingly, the third conductive line CL3, the conductive pattern layer CP, and the cover layer 122 may be electrically connected to each other.

In one or more embodiments, the third conductive line CL3 may include the source electrode SE (see FIG. 5) and/or the drain electrode DE (see FIG. 5). In one or more embodiments, the third conductive line CL3 may be formed concurrently or substantially simultaneously with the source electrode SE (see FIG. 5) and/or the drain electrode DE (see FIG. 5).

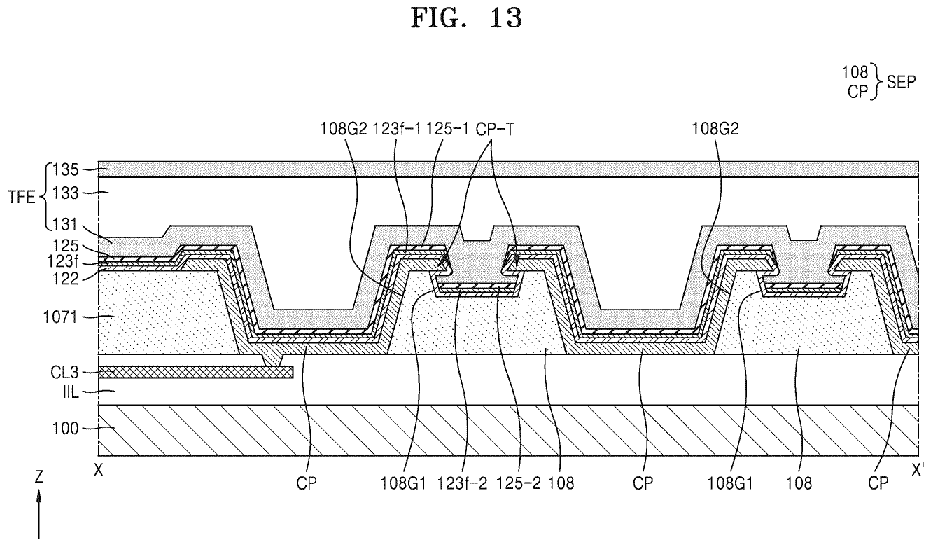

FIG. 13 is an example of a cross-sectional view of a part of the display panel 2 of FIG. 10, taken along the line X-X′, according to one or more embodiments.

From among features of the embodiments corresponding to FIG. 13, features other than those described below are substantially the same as the embodiments corresponding to FIG. 11.

Referring to FIG. 13, the third conductive line CL3 may be arranged within the inorganic insulating layer IIL. For example, a part of the inorganic insulating layer IIL may be between the third conductive line CL3 and the conductive pattern layer CP, or between the third conductive line CL3 and the organic pattern layer 108. In other words, an upper surface of the third conductive line CL3 may be spaced apart from a lower surface of the organic pattern layer 108. The third conductive line CL3 may overlap the second groove 108G2 of the organic pattern layer 108. In an area of the organic pattern layer 108 overlapping the second groove 108G2, the inorganic insulating layer IIL between the third conductive line CL3 and the conductive pattern layer CP may include a contact hole. The third conductive line CL3 and the conductive pattern layer CP may be in direct contact with each other through the contact hole. Through this, the third conductive line CL3, the conductive pattern layer CP, and the cover layer 122 may be electrically connected to each other.

In one or more embodiments, the third conductive line CL3 may include a same material as the gate electrode GE (see FIG. 5). In one or more embodiments, the third conductive line CL3 may be formed concurrently or substantially simultaneously with the gate electrode GE (see FIG. 5).

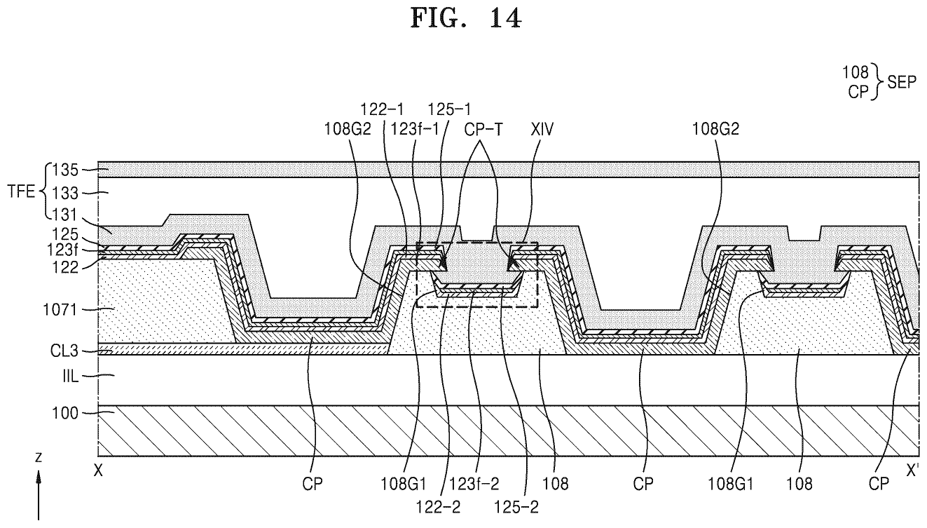

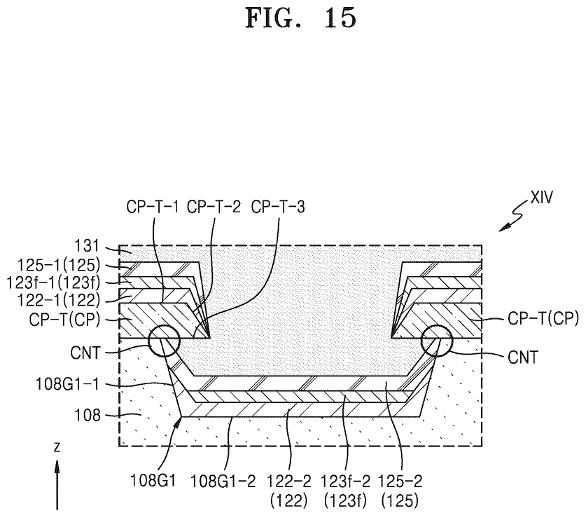

FIG. 14 is an example of a cross-sectional view of a part of the display panel 2 of FIG. 10, taken along the line X-X′, according to one or more embodiments. FIG. 15 is an enlarged cross-sectional view illustrating region XIV of FIG. 14.

Referring to FIGS. 14 and 15 together, the second portion 125-2 of the opposite electrode 125 may be in direct contact with the tip CP-T of the conductive pattern layer CP. As shown in FIG. 15, the tip CP-T of the conductive pattern layer CP may include an upper surface CP-T-1, a side surface CP-T-2, and a lower surface CP-T-3. The upper surface CP-T-1 and side surface CP-T-2 of the tip CP-T of the conductive pattern layer CP may be covered with the first portion 122-1. The second portion 125-2 of the opposite electrode 125 may be in direct contact with the lower surface CP-T-3 of the tip CP-T of the conductive pattern layer CP. For example, the second portion 125-2 of the opposite electrode 125 may include a contact portion CNT in contact with the lower surface CP-T-3 of the tip CP-T of the conductive pattern layer CP. The lower surface CP-T-3 of the tip CP-T other than the contact portion CNT may be covered with the first inorganic encapsulation layer 131.

In this case, the first groove 108G1 may include a side surface 108G1-1 and a lower surface 108G1-2. The lower surface 108G1-2 of the first groove 108G1 may be covered with the second portion 122-2 of the cover layer 122. A part of the side surface 108G1-1 of the first groove 108G1 may be covered with the second portion 122-2 of the cover layer 122. Another part of the side surface 108G1-1 of the first groove 108G1 may be covered with the second portion 125-2 of the opposite electrode 125. In other words, the side surface 108G1-1 of the first groove 108G1 may be fully covered with the second portion 122-2 of the cover layer 122 and the second portion 125-2 of the opposite electrode 125. The second portion 123f-2 of the functional layer 123f may be spaced apart from the side surface 108G1-1 of the first groove 108G1.

The opposite electrode 125 may include a conductive material. Because the second portion 125-2 of the opposite electrode 125 contacts the tip CP-T of the conductive pattern layer CP, each of the tips CP-T of the conductive pattern layer CP spaced apart from each other with the first groove 108G1 therebetween may be electrically connected to each other. Accordingly, each portion of the conductive pattern layer CP spaced apart from each other may be electrically connected to each other. The conductive pattern layer CP may form a single electrical path by the second portion 125-2 of the opposite electrode 125 electrically connecting the tips CP-T to each other. Accordingly, each of the separators SEP may form a single electrical path.

The third conductive line CL3 may be located on the inorganic insulating layer IIL. For example, the third conductive line CL3 may be located between the first organic insulating layer 1071 and the inorganic insulating layer IIL. A part of the third conductive line CL3 may overlap the second groove 108G2 of the organic pattern layer 108. In one or more embodiments, the third conductive line CL3 may be in direct contact with a part of the conductive pattern layer CP arranged in the second groove 108G2. For example, the upper surface of the third conductive line CL3 and the lower surface of the conductive pattern layer CP may be in direct contact with each other. Accordingly, the third conductive line CL3, the conductive pattern layer CP, and the second portion 125-2 of the opposite electrode 125 may be electrically connected to each other.

In one or more embodiments, the third conductive line CL3 may include the source electrode SE (see FIG. 5) and/or the drain electrode DE (see FIG. 5). In one or more embodiments, the third conductive line CL3 may be formed concurrently or substantially simultaneously with the source electrode SE (see FIG. 5) and/or the drain electrode DE (see FIG. 5).

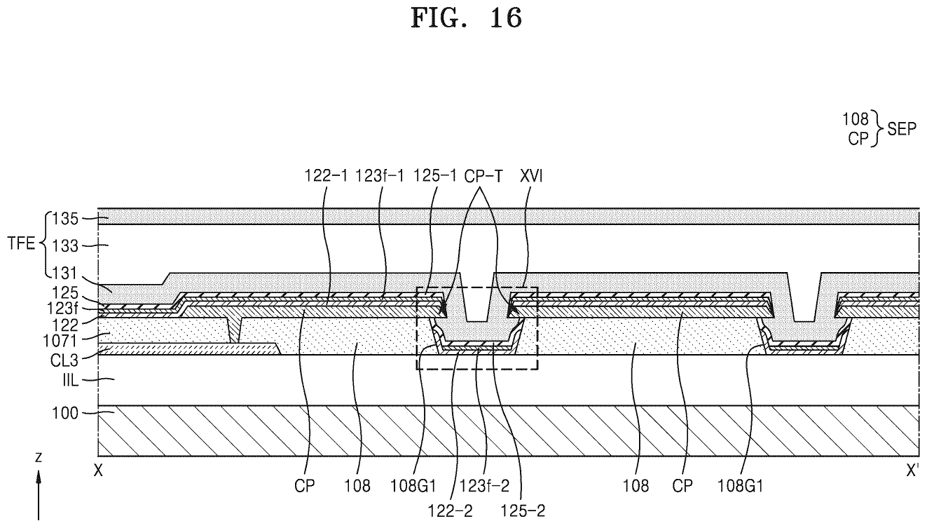

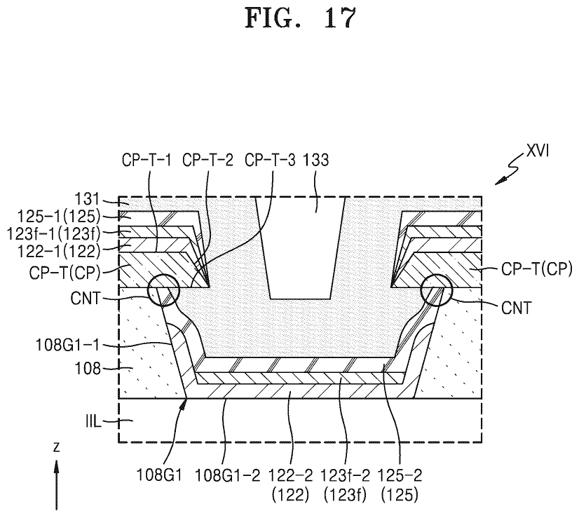

FIG. 16 is an example of a cross-sectional view of a part of the display panel 2 of FIG. 10, taken along the line X-X′, according to one or more embodiments. FIG. 17 is an enlarged cross-sectional view illustrating region XVI of FIG. 16.

Referring to FIGS. 16 and 17 together, the organic pattern layer 108 may not include a second groove, and may include only the first groove 108G1. In one or more embodiments, the first groove 108G1 may pass through the organic pattern layer 108. In one or more embodiments, the second portion 122-2 of the cover layer 122 may be in direct contact with the upper surface of the inorganic insulating layer IIL.

The second portion 125-2 of the opposite electrode 125 may directly contact the tip CP-T of the conductive pattern layer CP. Accordingly, the conductive pattern layer CP may form a single electrical path by the second portion 125-2 of the opposite electrode 125. A structure in which the conductive pattern layer CP forms a single electrical path is substantially identical to those described above with reference to FIGS. 14 and 15.

The third conductive line CL3 may be located on the inorganic insulating layer IIL. For example, the third conductive line CL3 may be located between the first organic insulating layer 1071 and the inorganic insulating layer IIL. The third conductive line CL3 may be in direct contact with the conductive pattern layer CP through a contact hole defined in the first organic insulating layer 1071 (or the organic pattern layer 108). Accordingly, the third conductive line CL3, the conductive pattern layer CP, and the second portion 125-2 of the opposite electrode 125 may be electrically connected to each other.

In one or more embodiments, the third conductive line CL3 may include the source electrode SE (see FIG. 5) and/or the drain electrode DE (see FIG. 5). In one or more embodiments, the third conductive line CL3 may be formed concurrently or substantially simultaneously with the source electrode SE (see FIG. 5) and/or the drain electrode DE (see FIG. 5).

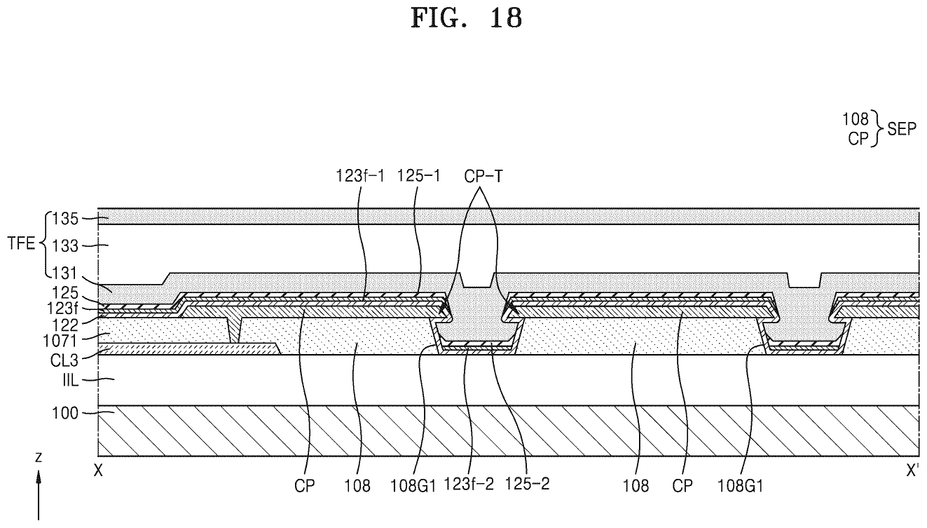

FIG. 18 is an example of a cross-sectional view of a part of the display panel 2 of FIG. 10, taken along the line X-X′, according to one or more embodiments.

Referring to FIG. 18, the organic pattern layer 108 may not include a second groove, and may include the first groove 108G1. In one or more embodiments, the first groove 108G1 may pass through the organic pattern layer 108.

The cover layer 122 may be located on the organic pattern layer 108, and the cover layer 122 and may be integrally formed. Accordingly, the cover layer 122 may entirely cover the organic pattern layer 108 and the conductive pattern layer CP. For example, the cover layer 122 may continuously extend to cover the upper surface of the conductive pattern layer CP, the side and lower surfaces of the tip CP-T of the conductive pattern layer CP, and the first groove 108G1. Accordingly, the cover layer 122 may cover the side and upper surfaces of the organic pattern layer 108 in which the first groove 108G1 is formed. Because the cover layer 122 covers the first groove 108G1, the second portion 123f-2 of the functional layer 123f and the second portion 125-2 of the opposite electrode 125 may be spaced apart from the side surface of the organic pattern layer 108 in which the first groove 108G1 is formed. In one or more embodiments, the cover layer 122 may be in direct contact with the upper surface of the inorganic insulating layer IIL within the first groove 108G1.

The cover layer 122 and the conductive pattern layer CP may include a conductive material. Accordingly, the tips CP-T of the conductive pattern layer CP spaced apart from each other with the first groove 108G1 therebetween may be electrically connected to each other by the cover layer 122. Because the cover layer 122 extends continuously, each of portions of the conductive pattern layer CP arranged apart from each other may all be electrically connected to each other. Accordingly, each of the separators SEP may be electrically connected to each other, and may form a single electrical path.

The third conductive line CL3 may be located on the inorganic insulating layer IIL. For example, the third conductive line CL3 may be located between the first organic insulating layer 1071 and the inorganic insulating layer IIL. The third conductive line CL3 may be in direct contact with the conductive pattern layer CP through the contact hole defined in the first organic insulating layer 1071 (or the organic pattern layer 108). Accordingly, the third conductive line CL3, the conductive pattern layer CP, and the cover layer 122 may be electrically connected to each other.

In one or more embodiments, the third conductive line CL3 may include the source electrode SE (see FIG. 5) and/or the drain electrode DE (see FIG. 5). In one or more embodiments, the third conductive line CL3 may be formed concurrently or substantially simultaneously with the source electrode SE (see FIG. 5) and/or the drain electrode DE (see FIG. 5).

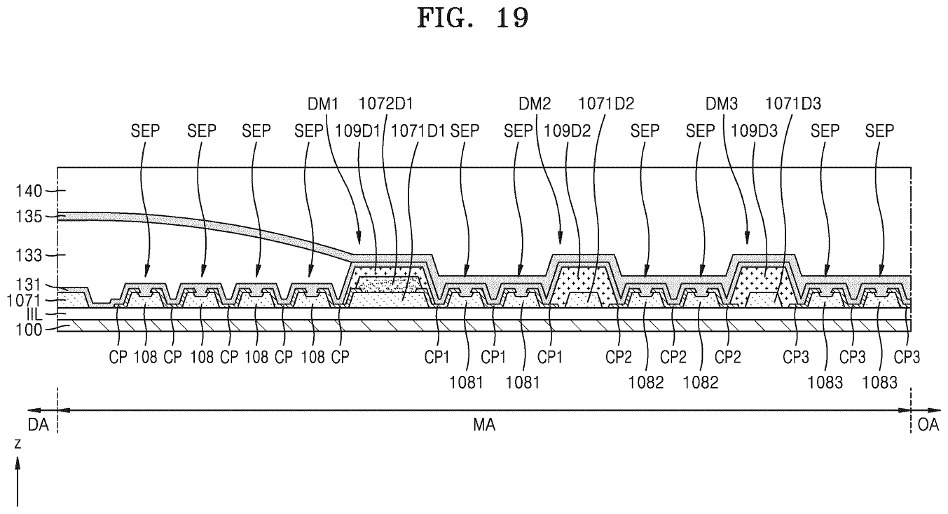

FIG. 19 is a cross-sectional view illustrating a part of a display panel according to one or more embodiments.

FIG. 19 is a cross-sectional view showing the entire intermediate area MA. Referring to FIG. 19, the display area DA is shown on the left side of the intermediate area MA, and the opening area OA is shown on the right side of the intermediate area MA. A first dam DM1, a second dam DM2, and a third dam DM3 may be arranged sequentially from left to right, or from the display area DA toward the opening area OA. The plurality of separators SEP may be arranged on the left side of the first dam DM1, between the first dam DM1 and the second dam DM2, between the second dam DM2 and the third dam DM3, and on the right side of the third dam DM3. For convenience of description, the separators SEP on the left side of the first dam DM1 may include the organic pattern layer 108 and the conductive pattern layer CP, the separators SEP between the first dam DM1 and the second dam DM2 may include a first organic pattern layer 1081 and a first conductive pattern layer CP1, the separators SEP between the second dam DM2 and the third dam DM3 may include a second organic pattern layer 1082 and a second conductive pattern layer CP2, and the separators SEP on the right side of the third dam DM3 may include a third organic pattern layer 1083 and a third conductive pattern layer CP3.

The first dam DM1 may include a first layer 1071D1, a second layer 1072D1, and a third layer 109D1. The second dam DM2 may include a first layer 1071D2 and a second layer 109D2. The third dam DM3 may include a first layer 1071D3 and a second layer 109D3.

The first layer 1071D1 of the first dam DM1, the first layer 1071D2 of the second dam DM2, and the first layer 1071D3 of the third dam DM3 may include a same material as the first organic insulating layer 1071, the organic pattern layer 108, the first organic pattern layer 1081, the second organic pattern layer 1082, and the third organic pattern layer 1083. In one or more embodiments, the first organic insulating layer 1071, the organic pattern layer 108, the first layer 1071D1 of the first dam DM1, the first organic pattern layer 1081, the first layer 1071D2 of the second dam DM2, the second organic pattern layer 1082, the first layer 1071D3 of the third dam DM3, and the third organic pattern layer 1083 may be formed concurrently or substantially simultaneously.

The second layer 1072D1 of the first dam DM1 may include a same material as the second organic insulating layer 1072 (see FIG. 5). In one or more embodiments, the second layer 1072D1 of the first dam DM1 and the second organic insulating layer 1072 (see FIG. 5) may be formed concurrently or substantially simultaneously.

The third layer 109D1 of the first dam DM1, the second layer 109D2, and the second layer 109D3 of the third dam DM3 may include a same material as the pixel-defining layer 109 (see FIG. 5). In one or more embodiments, the pixel-defining layer 109 (see FIG. 5) may be formed concurrently or substantially simultaneously with the third layer 109D1 of the first dam DM1, the second layer 109D2 of the second dam DM2, and the second layer 109D3 of the third dam DM3.

The conductive pattern layer CP, the first conductive pattern layer CP1, the second conductive pattern layer CP2, and the third conductive pattern layer CP3 may include a same material as each other. In one or more embodiments, the conductive pattern layer CP, the first conductive pattern layer CP1, the second conductive pattern layer CP2, and the third conductive pattern layer CP3 may be formed concurrently or substantially simultaneously. A connection structure of a conductive, described with reference to FIGS. 6 to 18, may be formed in the conductive pattern layer CP. However, one or more embodiments are not limited thereto, and the structure may be formed in one or more layers from among the first conductive pattern layer CP1, the second conductive pattern layer CP2, and the third conductive pattern layer CP3.

In one or more embodiments, a cover layer may be located on the separators SEP, and may integrally extend within the intermediate area MA. In this case, the conductive pattern layer CP, the first conductive pattern layer CP1, the second conductive pattern layer CP2, and the third conductive pattern layer CP3 may all be electrically connected to each other, and may form a single electrical path within the intermediate area MA. In this case, the connection structure of the conductive line, described with reference to FIGS. 10 to 18, may be applicable.

In one or more other embodiments, each of portions of the conductive pattern layer CP, the first conductive pattern layer CP1, the second conductive pattern layer CP2, and the third conductive pattern layer CP3 may be spaced apart from each other, and may form a separate electrical path. In this case, the conductive line described above may be selectively connected to one of each of the portions of the conductive pattern layer CP, the first conductive pattern layer CP1, the second conductive pattern layer CP2, and the third conductive pattern layer CP3. In this case, the connection structure of the conductive line, described with reference to FIGS. 6 to 9, may be applicable.

According to the one or more embodiments, a conductive pattern portion of a separator around an opening area of a display panel may be used to connect lines, so that a length of a line bypassing the opening area may be reduced. Furthermore, as the length of the line is reduced, resistance of the line may also be reduced. However, these aspects are only examples, and the scope of the one or more embodiments is not limited thereby.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display panel comprising:
a substrate comprising a display area, an opening area within the display area, and an intermediate area between the opening area and the display area;
a light-emitting diode in the display area, and comprising a sub-pixel electrode, an opposite electrode above the sub-pixel electrode, and an intermediate layer between the sub-pixel electrode and the opposite electrode;
an organic pattern layer in the intermediate area above the substrate, and defining a first groove and a second groove;
a conductive pattern layer in the second groove, and comprising a tip having an end protruding toward a center of the first groove in plan view; and
a line electrically connected to the conductive pattern layer, and passing through the display area.

2. The display panel of claim 1, further comprising a cover layer above the conductive pattern layer, and comprising a conductive material.

3. The display panel of claim 2, wherein the cover layer comprises a first portion above an upper surface of the conductive pattern layer, and a second portion in the first groove and separated from the first portion.

4. The display panel of claim 3, wherein the first portion at least partially covers the tip of the conductive pattern layer.

5. The display panel of claim 2, wherein the cover layer continuously extends along an upper surface of the conductive pattern layer, side and lower surfaces of the tip, and an upper surface of a portion of the organic pattern layer in the first groove.

6. The display panel of claim 2, wherein the cover layer and the sub-pixel electrode comprise a same material.

7. The display panel of claim 1, wherein the line is integral with the conductive pattern layer.

8. The display panel of claim 1, wherein the line is under the conductive pattern layer, and contacts the conductive pattern layer in an area in which the line overlaps the second groove.

9. The display panel of claim 8, wherein an insulating layer is between the conductive pattern layer and the line, and
wherein the line is electrically connected to the conductive pattern layer through a contact hole in the insulating layer.

10. The display panel of claim 1, wherein the line comprises a scan line, a data line, or a voltage line.

11. The display panel of claim 1, wherein the conductive pattern layer surrounds the opening area in plan view.

12. The display panel of claim 1, wherein the opposite electrode of the light-emitting diode extends toward the intermediate area, and comprises a first portion and a second portion separated from each other with respect to the tip, the second portion being in the first groove and directly contacting the tip of the conductive pattern layer.

13. A display panel comprising:
a substrate comprising a first area, a second area at least partially surrounding the first area, and a third area between the first area and the second area;
a light-emitting diode in the second area, and comprising a sub-pixel electrode, an opposite electrode above the sub-pixel electrode, and an intermediate layer between the sub-pixel electrode and the opposite electrode;
a separator in the third area;
a cover layer above the separator, and comprising a conductive material; and
a line passing through the second area,
wherein the separator comprises:
an organic pattern layer above the substrate, and defining a groove; and
a conductive pattern layer electrically connected to the line, above an upper surface of the organic pattern layer, and comprising a tip extending toward a center of the groove in plan view and having at least a portion covered by the cover layer.

14. The display panel of claim 13, wherein the cover layer comprises a first portion above the conductive pattern layer, and a second portion in the groove and separated from the first portion.

15. The display panel of claim 13, wherein the cover layer continuously extends by entirely covering the conductive pattern layer and the organic pattern layer in the groove.

16. The display panel of claim 13, wherein the cover layer and the sub-pixel electrode comprise a same material.

17. The display panel of claim 13, wherein the line is integral with the conductive pattern layer.

18. The display panel of claim 13, wherein the line is between the substrate and the conductive pattern layer, and contacts the conductive pattern layer.

19. The display panel of claim 18, wherein an insulating layer is between the conductive pattern layer and the line, and
wherein the line is electrically connected to the conductive pattern layer through a contact hole in the insulating layer.

20. The display panel of claim 13, wherein the line comprises a scan line, a data line, or a voltage line.

21. The display panel of claim 13, wherein the separator surrounds the first area in plan view.

22. The display panel of claim 13, further comprising an electrode layer comprising a first portion above an upper surface of the conductive pattern layer, and a second portion in the groove and separated from the first portion.

23. The display panel of claim 22, wherein the electrode layer is above the cover layer.

24. The display panel of claim 22, wherein the second portion of the electrode layer directly contacts the tip of the conductive pattern layer.

25. The display panel of claim 22, wherein the electrode layer and the opposite electrode comprise a same material.
